(19) United States
(12) Patent Application Publication
(10) Pub. No.: US 2009/0114268 A1
(43) Pub. Date: May 7, 2009

(54) REINFORCED SOLAR CELL FRAMES

(75) Inventors: Benyamin Buller, Cupertino, CA (US); Thomas Paul Frangesh, Campbell, CA (US)

Correspondence Address: JONES DAY, 222 EAST 41ST ST, NEW YORK, NY, 10017, US

(73) Assignee: Solyndra, Inc., Fremont, CA (US)

(21) Appl. No.: 11/934,631

(22) Filed: Nov. 2, 2007

Related U.S. Application Data
(60) Provisional application No. 60/859,188, filed on Nov. 15, 2006.
(60) Provisional application No. 60/859,213, filed on Nov. 15, 2006.
(60) Provisional application No. 60/859,212, filed on Nov. 15, 2006.
(60) Provisional application No. 60/859,033, filed on Nov. 15, 2006.
(60) Provisional application No. 60/859,215, filed on Nov. 15, 2006.
(60) Provisional application No. 60/861,162, filed on Nov. 27, 2006.
(60) Provisional application No. 60/901,517, filed on Feb. 14, 2007.

(51) Int. Cl. H01L 31/048

(52) U.S. Cl. 136/251

(57) ABSTRACT

A solar assembly apparatus is provided that comprises one or more photovoltaic modules, a first end rail to which the first ends of the one or more photovoltaic modules are fixed and a first stiffening member to which the first end rail is attached. In some instances, the one or more photovoltaic modules are a plurality of electrically-interconnected elongated photovoltaic modules forming an array and each elongated photovoltaic module in the plurality of elongated photovoltaic modules is elongated along an axis and has a first end and a second end that are axially opposite each other. Furthermore, in such instances, each elongated photovoltaic module in the plurality of elongated photovoltaic modules has photovoltaic surface portions facing away from the axis in different directions to receive light to generate electricity.

### CROSS REFERENCE TO RELATED APPLICATIONS

This Application claims priority to U.S. patent Application Nos. 60/859,188, 60/859,213, 60/859,212, 60/859,033, and 60/859,215, each filed Nov. 15, 2006, as well as U.S. patent Application No. 60/861,162, filed Nov. 27, 2006 and 60/901,517, filed Feb. 14, 2007, each of which is hereby incorporated by reference herein in its entirety.

### TECHNICAL FIELD

This disclosure relates to solar cell assemblies. More specifically, this disclosure relates to systems and methods for reinforcing a frame.

### BACKGROUND

A solar assembly includes an array of photovoltaic modules that are electrically connected to output terminals. The modules output electricity through the terminals when exposed to sunlight.

### BRIEF DESCRIPTION OF THE DRAWINGS

FIG. 1 is a perspective view of a solar panel, including a one-dimensional array of photovoltaic elongated photovoltaic modules mounted in a frame;

FIG. 2A is an exploded view of the panel;

FIG. 2B is a close up view of an embodiment of a reinforced end rail of the solar cell frame;

FIG. 2C illustrates close up front and side views of an embodiment of a reinforced end rail of the solar cell frame;

FIG. 2D illustrates close up front and side views of an embodiment of a reinforced end rail of the solar cell frame;

FIG. 2E illustrates close up front and side views of an embodiment of a reinforced end rail of the solar cell frame;

FIG. 2F illustrates close up front and side views of an embodiment of a reinforced end rail of the solar cell frame;

FIG. 3A is a sectional view of an exemplary one of the modules;

FIG. 3B is a sectional view taken at line 3B-3B of FIG. 3A;

FIG. 4 is a perspective view of a rail of the frame;

FIG. 5 is a sectional view showing interconnecting parts of the module and the rail;

FIG. 6 is a top view of the array, showing electrical lines connecting the modules in parallel;

FIG. 7 is a side sectional view of the array, showing the spatial relationship of the modules to each other and to a reflective backplate;

FIG. 8 is a sectional view similar to FIG. 7, showing the array exposed to sunlight;

FIG. 9 is a sectional view similar to FIG. 5, with an alternative configuration of the interconnecting parts of the module and the rail;

FIG. 10 is a sectional view similar to FIGS. 5 and 9, showing another alternative configuration of the interconnecting parts of the module and the rail;

FIG. 11 is a top view similar to FIG. 6, showing electrical lines connecting the modules in series;

FIGS. 12-14 are perspective views of alternative modules;

FIG. 15 is a sectional view of a two-dimensional array of the modules; and

FIG. 16 is a perspective view of an embodiment of the present application with flat solar cell panels.

Like reference numerals refer to corresponding parts throughout the several views of the drawings. Dimensions are not drawn to scale.

### DESCRIPTION

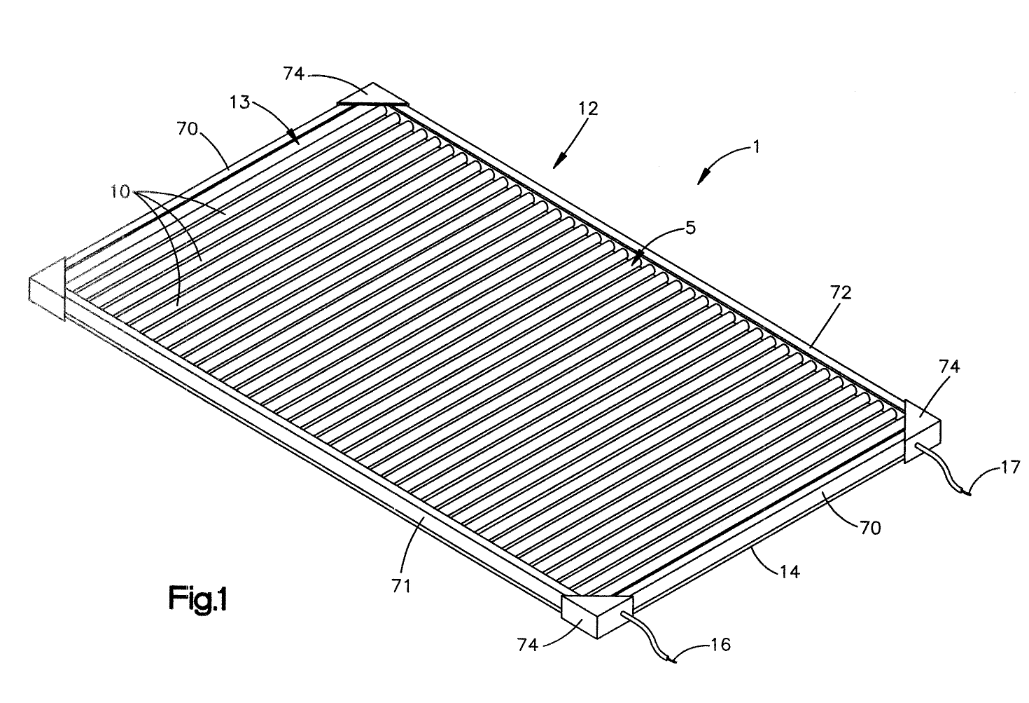

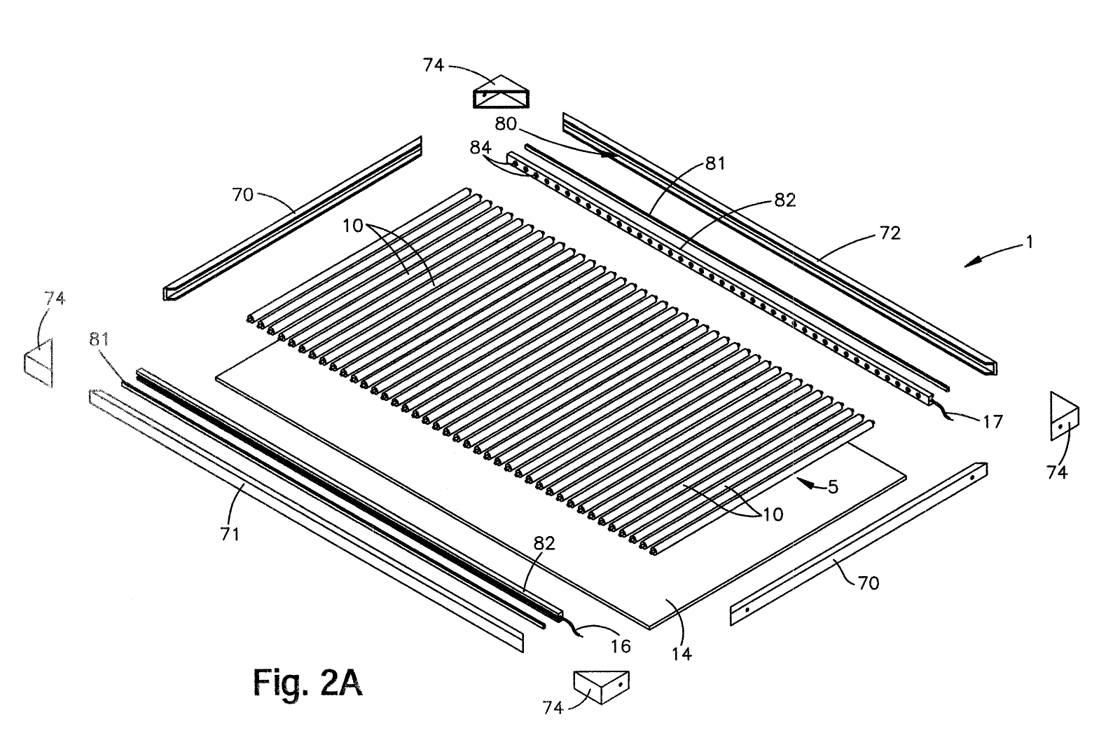

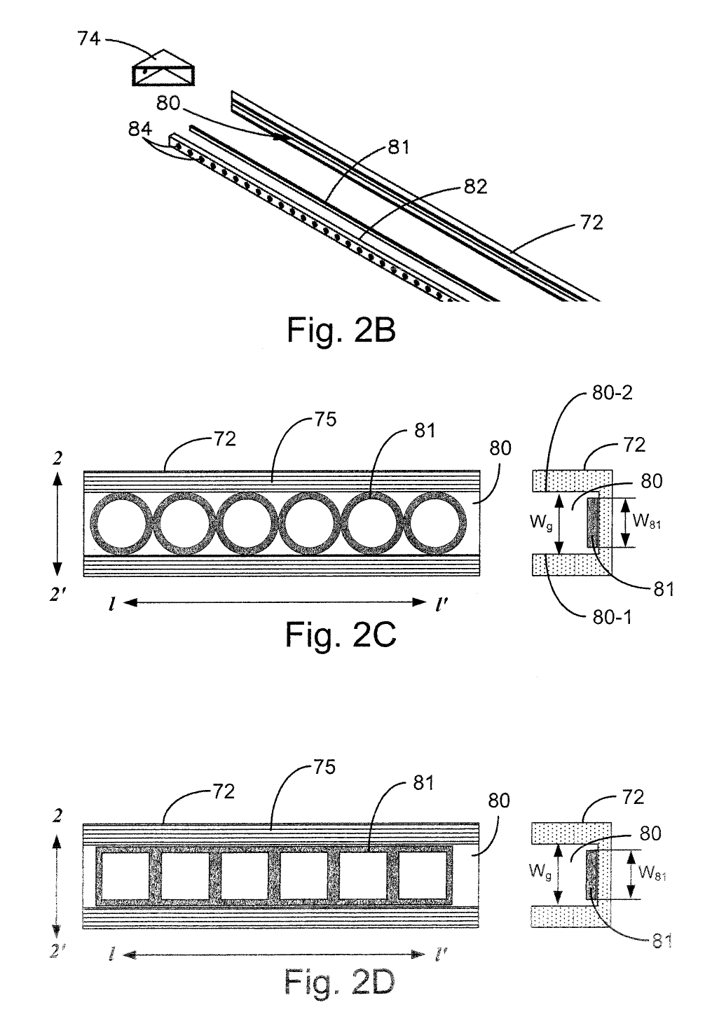

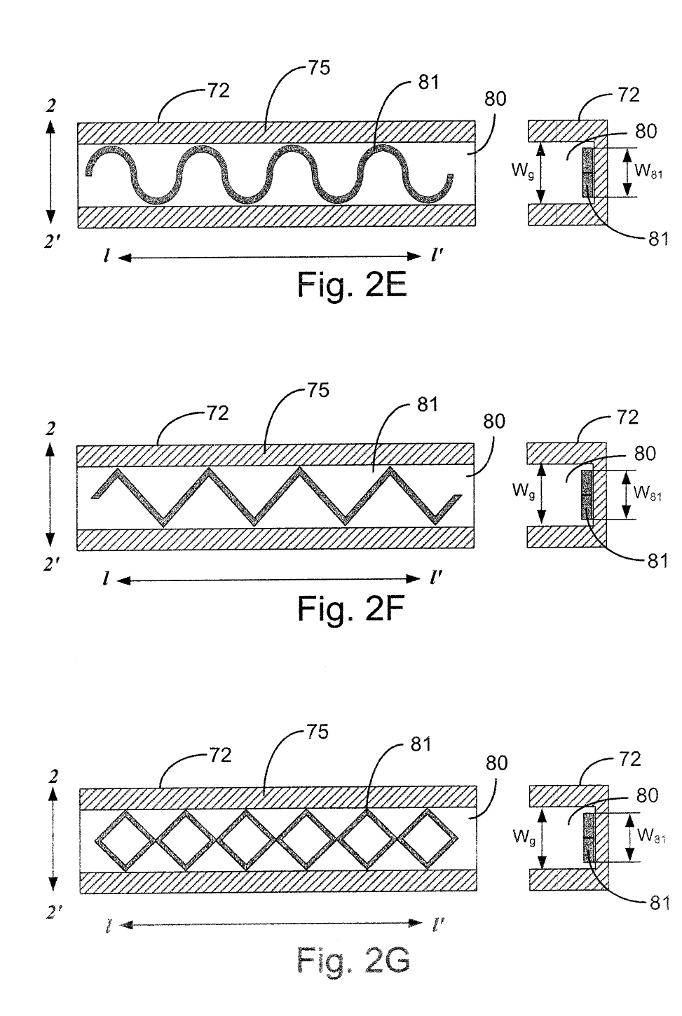

The apparatus shown in FIGS. 1-2 has parts that are examples of the elements recited in the claims. It includes examples of how a person of ordinary skill in the art can make and use the claimed apparatus. It is described here to meet the requirements of enablement and best mode without imposing limitations that are not recited in the claims. Features from different embodiments described below can be combined together into one embodiment without departing from the scope of the claims.

The apparatus 1 is a solar panel. It includes a one-dimensional array 5 of parallel or near parallel elongated photovoltaic modules 10 secured in a frame 12. The frame 12 has a front opening 13 configured to receive sunlight. The frame 12 can be mounted in front of a backplate 14 with a reflective surface such as a mirror surface or white coating. The reflective surface is preferably parallel with the module axes A. The photovoltaic modules 10 output electricity through two outlet terminals 16 and 17 when exposed to light.

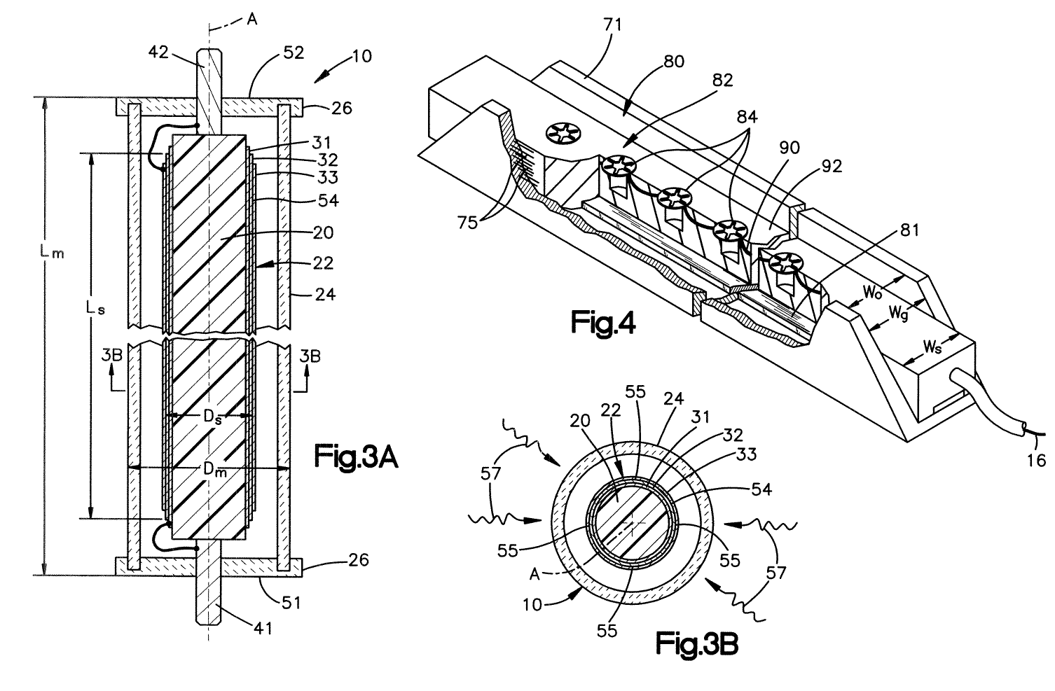

In some embodiments, the modules 10 in a given frame 12 have identical shapes and dimensions. In other embodiments, some of the modules 10 in a given frame 12 have shapes and/or dimensions that are different than other modules in the given frame 12. As exemplified by a module 10 shown in FIGS. 3A-3B, each module 10 can include a core 20 centered on an axis A in embodiments where module 10 is cylindrical. The core 20 can be solid or hollow, electrically insulating or conductive. The core 20 can be surrounded by a photovoltaic cell 22 extending fully about the axis A. The cell 22 can itself be surrounded by a transparent protective tube 24 capped by two axially opposite caps 26.

Examples for such a configuration including the tube 24 and caps 26 are illustrated in United States Patent Publication Number 20070215195, which is hereby incorporated by reference herein. In some instances, caps 26 form a hermetic seal as described in U.S. patent application Ser. No. 11/437,928, which is hereby incorporated by reference herein.

In embodiments where modules 10 are cylindrical, the length Lₛ of the photovoltaic surface 54 of such modules 10 is greater than, and preferably over five times or over twenty times greater than, the diameter Dₛ of the photovoltaic surface 54. Similarly, the length Lm of the module 10 is greater than, and preferably over five times or over twenty times greater than, the diameter Dₘ of the diameter of the module 10. The module's length and diameter in this example correspond to the lengths and diameters of the module's outer tube 26.

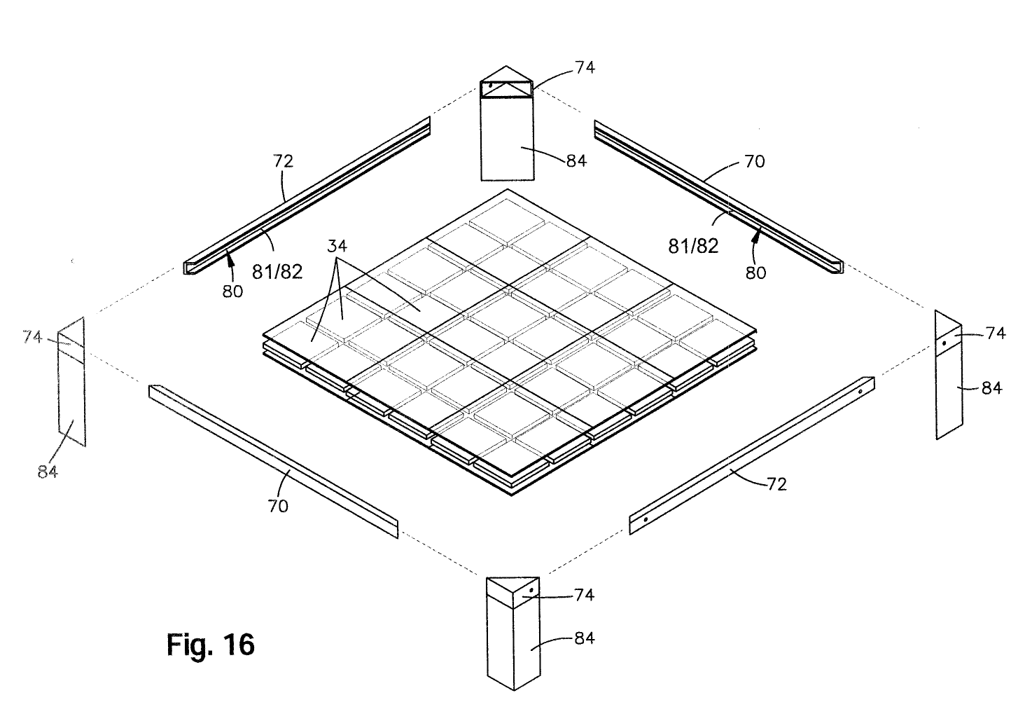

In some embodiments, there is only a single module 10 within frame 12 and this single module 10 is flat planar rather than cylindrical (depicted as 34 in FIG. 16). In some embodiments, there is more than one flat planar module within frame 12, as depicted in FIG. 16. Such modules have a core that is either an electrically insulating solid or conductive solid. In some embodiments, the core has two faces: a first face that is exposed to unreflected direct sunlight and a second face that receives reflected direct sunlight. All or a portion of each face is optionally coated with a photovoltaic cell 22. In some embodiments, not shown in FIG. 16 termed bifacial and/or omnifacial embodiments, both faces are coated with a photovoltaic cell 22. In some embodiments, termed monofacial embodiments, only one face is coated with a photovoltaic cell 22. In embodiments where there is a single flat panel module 34 in frame 12, the length and width of the frame 12 is each independently between 2 centimeters and five meters.

In embodiments where modules 10 are cylindrical or flat planar, the photocell 22 typically has three layers—an inner layer conductive layer 31 overlying the core 20 (where core 20 is also know as a substrate), a middle semiconductor photovoltaic layer 32 overlying inner layer conductive layer 31, and a transparent conductive outer layer 33 overlying middle semiconductor photovoltaic layer.

In some embodiments, the middle semiconductor photovoltaic layer 32 comprises an absorber layer and a junction partner layer, where the junction partner layer is disposed on the absorber layer. In some embodiments, the absorber layer is copper-indium-gallium-diselenide and the junction partner layer is In₂Se₃, In₂S₃, ZnS, ZnSe, CdlnS, CdZnS, ZnIn₂Se₄, Zn₁₋ₓMgₓO, CdS, SnO₂, ZnO, ZrO₂, or doped ZnO. In some embodiments, the middle semiconductor photovoltaic layer 32 is between 0.5 μm and 2.0 μm thick. In some embodiments a composition ratio of Cu/(In +Ga) in the absorber layer is between 0.7 and 0.95. In some embodiments, a composition ratio of Ga/(In +Ga) in the absorber layer is between 0.2 and 0.4. In some embodiments, the absorber layer comprises CIGS having a <110> crystallographic orientation, a <112> crystallographic orientation, or CIGS that is randomly oriented.

The inner and outer layers 31 and 33 are typically connected to an anode output contact 41 and a cathode output contact 42 at the axially opposite ends 51 and 52 of the cell 22. In some embodiments, outer layer 33 is made of carbon nanotubes, tin oxide SnOₓ (with or without fluorine doping), indium-tin oxide (ITO), doped zinc oxide (e.g., aluminum doped zinc oxide), indium-zinc oxide, doped zinc oxide, aluminum doped zinc oxide, gallium doped zinc oxide, boron dope zinc oxide, or any combination thereof. Carbon nanotubes are commercially available, for example from Eikos (Franklin, Mass.) and are described in U.S. Pat. No. 6,988,925, which is hereby incorporated by reference herein in its entirety. In some embodiments, outer layer 33 is eitherp-doped or n-doped. In general, outer layer 33 is preferably made of a material that has very low resistance, suitable optical transmission properties (e.g., greater than 90%), and a deposition temperature that will not damage underlying layers. In some embodiments, outer layer 33 is an electrically conductive polymer material such as a conductive polytiophene, a conductive polyaniline, a conductive polypyrrole, a PSS-doped PEDOT (e.g., Bayrton), or a derivative of any of the foregoing. In some embodiments, outer layer 33 comprises more than one layer, including a first layer comprising tin oxide SnOₓ (with or without fluorine doping), indium-tin oxide (ITO), indium-zinc oxide, doped zinc oxide (e.g., aluminum doped zinc oxide) or a combination thereof and a second layer comprising a conductive polytiophene, a conductive polyaniline, a conductive polypyrrole, a PSS-doped PEDOT (e.g., Bayrton), or a derivative of any of the foregoing. Additional suitable materials that can be used to form outer layer 33 are disclosed in United States Patent publication 2004/0187917A1 to Pichler, which is hereby incorporated by reference herein in its entirety.

As shown in FIGS. 3A-3B, the photovoltaic middle layer 32 has a photovoltaic surface 54 that receives light to photovoltaically generate electricity. The electricity is conducted through the conductive layers 31, 33 to be output through the contacts 41, 42. The photovoltaic surface 54 in this example is cylindrically tubular. It thus includes an infinite number of contiguous surface portions 55, each facing away from the axis A in a different direction. These include, with reference to FIG. 3B, the four orthogonal directions up, down, left and right. Therefore, the cell 32 in this example, and thus the module 10, can photovoltaically generate electricity from light (exemplified by arrows 57) directed toward the module 10 from any radially-inward (i.e., toward the axis A) direction.

As shown in FIG. 1, the frame 12 includes two axially-extending side rails 70 and laterally-extending first and second end rails 71 and 72. In some embodiments, end rails 71 and 72 have a length of between 10 centimeters and four meters. In this example, the rails 70, 71 and 72 are held together by corner brackets 74. The end rails 71, 72 rigidly secure the modules 10 in place and are themselves rigidly secured together by the side rails 70. Alternatively, the rails 70, 71 and 72 can be conjoined by means other than the brackets, such as a fit-connection or a pressure-connection between the rails 70, 71, and 72, as well as fasteners and/or adhesives. In some embodiments, side rails 70 have a length of between 10 centimeters and four meters.

The rails 70, 71, 72 can be extruded and stocked in long lengths from which shorter lengths can be cut to match the individual length needed for each application. To simplify warehousing and manufacturing, the side rails 70 can be cut from the same stock material as the end rails 71, 72.

The rails 70, 71, 72 can be formed of fiber reinforced plastic, such as with pultruded fibers 75 extending along the full length of the rail as illustrated by the first end rail 71 in FIG. 4. The fibers 75 resist stretching of the rail 71 to help maintain the preset center spacing of the modules 10 (in embodiments where such spacing is found such as embodiments where modules 10 are cylindrical or have some closed form shape), while enabling flexing of the respective rail. Examples of pultruded fibers are glass fibers and organic fibers such as aramid and carbon fibers, and compound materials. They can take various forms, such as roving strands, mats or fabrics, which can take different orientations in relation to the shapes and dimension of the final products formed during a pultrusion process. Alternative materials for the rails 70, 71, 72 are other plastics, metals, extruded materials, and other types of preformed and cut materials. Corner support member 74 are used to hold the end rail 72 and side rail 70, or end rail 71 and side rail 70 together to provide further structure integrity to the frame 12.

The end rails 71, 72 in this example are identical, and described with reference to the first end rail 71 in FIG. 4. The end rail 71 has a laterally extending groove 80. In some embodiments, a stiffening member 81 can be adhered to the bottom surface of the groove 80 to stiffen the rail 71. The stiffening member 81 in this example is narrower than the width of the groove 80. In some embodiments, the stiffening member 81 fully extends the width w of the groove 80.

In some embodiments, not depicted in FIG. 2A, the socket strip 82 is a ribbon-like structure which includes a chain of sockets 84. In some embodiments, the socket strip 82 is made of rubber or plastic with embedded sockets 84 or the like for electrical connections. A stiffening member 81 is adhered to one side of the laterally extending groove 80. In some embodiments, the stiffening member 81 is such that it adheres to the bottom of the groove 80. In such embodiments, the stiffening member 81 is placed between the laterally extending groove 80 in end rail 72 and the socket strip 82, as depicted in FIGS. 2, 4, 5, 9 and 10. Unlike the reinforcement fibers 75, which are embedded into end rails 71 72, or 70, the stiffening member 81 provides external reinforcement to the end rails 71 and 72. In some embodiments, the stiffening member 81 may be added to side rails 70 to further reinforce the integrity of the frame 12.

In some embodiments, the stiffening members 81 are metal bars made of aluminum, copper, iron, titanium, zinc, or a combination thereof (e.g. in an alloy form such as steel). In some embodiments, the stiffening members 81 are made of non-metal materials, for example, wood. More details on the structure and configuration of the stiffening member 81 are disclosed below.

A socket strip 82 in the groove 80 can be adhered to both the top of the stiffening member 81 and the bottom of the groove 80. The socket strip 82 in this example contains a chain of metal socket contacts 84 interconnected by an electrical bus line 90, all overmolded by a rubber sheath 92. The sheath 92 can electrically insulate the bus line 90 and secure the socket contacts 84 in place at a predetermined center spacing. The rail 71 accordingly contains the strip 82, and thus also the sockets 84 and electrical lines 90 of the strip 82. The width Wₛ of the strip 82 can approximately equal the width W_{g} of the groove 80 so as to fit snugly in the groove 80.

In some embodiments, electrical potting and encapsulation material is added to facilitate the connection between stiffening members 81, socket strips 82 and the grooves 80 of the respective rails 71 and 72. A more detailed description of electrical potting and encapsulation materials is provided below.

Alternatively, the width Wₒ of the opening of the groove 80 could be smaller than the width Wₛ of the strip 82, while the width Wₛ of the strip 82 is be substantially equal to or smaller than the width W_{g} of the groove. In this case, a lip or lip-like member of the groove 80 could be used to at least partially restrict the movement of the strip. In this case, the strip could be inserted into the channel or groove 80 from the end, or pressure-placed past the lip at the opening of the groove 80 into the groove 80 in the rail 71.

The sheath 92 can be flexible, and even rubbery, to reduce stress in the modules 10 and facilitate manipulation when being connected to the modules 10 or inserted into the rail 71. If sufficiently flexible, the sheath 92 can be manufactured in long lengths and stocked in a roll. Shorter lengths can be cut from the roll as needed, to match the length and number of sockets 84 needed for each application. Even if made flexible, the sheath 92 is preferably substantially incompressible and inextensible to maintain the center spacing of the modules 10. The sheath 92 can alternatively be rigid to enhance rigidity of the rail 71 or have rigid and flexible portions.

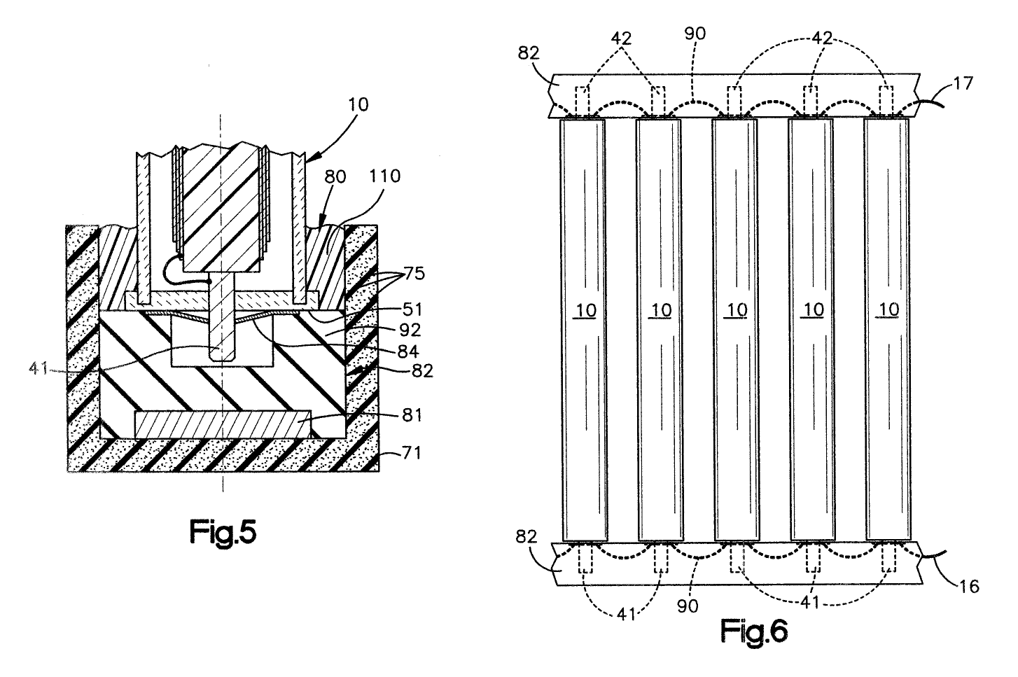

As illustrated with reference to one end 51 of one module 10 shown in FIG. 5, each electrical contact 41, 42 of each module 10 can be both electrically coupled to and mechanically secured by a corresponding socket contact 84. Potting material 110 can fill the groove 80 to encase the socket contacts 84 and form a seal with each module 10 fully about the module 10. This can isolate and hermetically seal the socket contacts 84 and module contacts 41, 42 from environmental air, moisture and debris, and further isolate any electrical connection between the device and the frame. The potting material 110 further stiffens the orientation of the ends 51, 52 of each module 10. Bowing of the module 10 from gravity and vibration is less than it would be if its ends 51, 52 were free to pivot about the socket 84. The reduction in bowing reduces the chance of the modules 10 breaking or contacting each other and helps maintain the predetermined center spacing of the modules 10.

As shown in FIG. 6, the electrical line 90 in the first end rail 71 connects all the module anodes 41 to the common anode terminal 16. The electrical line 90 in the second end rail 72 connects all the module cathodes 42 to the common cathode terminal 17. The modules 10 are thus connected in parallel. In this manner, the electrical connection between the modules 10 are defined by two bus-like connections embedded within the framework. Additionally, the connections between the electrical contacts 42 may use ribbon-like or wire-like materials, so that any relative movement of the opposing rails, or relative movement between any two modules 10 does not impart stresses on the module contacts 41, 42 or the modules 10 themselves.

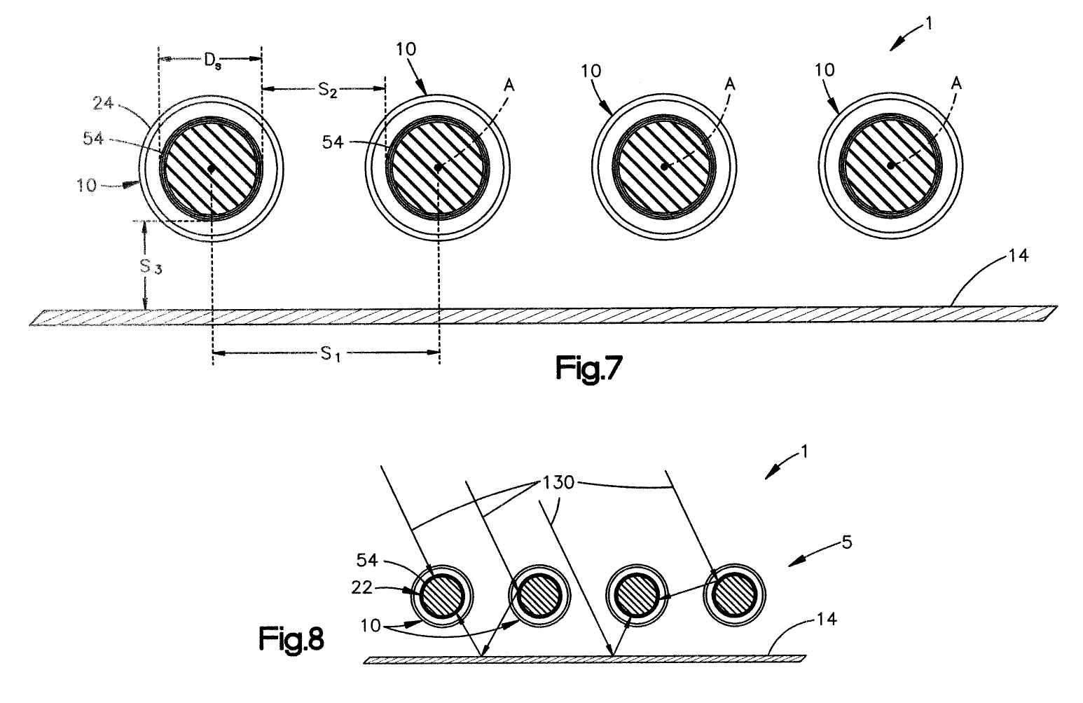

In the assembled panel 1 shown in FIG. 7, the center spacing S₁ between modules 10 equals the diameter Dₛ of the photovoltaic surface 54 plus the spacing S₂ between adjacent photovoltaic surfaces 54. The spacing S₂ is about 0.5 to about 2 times the diameter Dₛ. The spacing S₃ between each photovoltaic surface 54 and the reflective surface 14 is preferably about 0.5 to about 2 times the diameter Dₛ.

FIG. 8 shows the panel 1 exposed to sunlight 130. As shown, the light 130 can impinge upon each photocell 22 in multiple ways. Light passing through the array 5, between photocells 22, is reflected by the reflective surface 14 back toward the array 5 to impinge upon one of the photocells 22. The light can also reflect off one cell 22 to impinge a neighboring cell 22.

Referring to FIG. 2A, one method of assembling the panel 10 includes the following sequence of steps. First, the stiffening members 81 and socket strips 82 are secured in the grooves 80 of the respective rails 71, 72. Then, the anode contacts 41 (FIG. 3A) of the modules 10 are connected to the socket strip 82 in the first end rail 71, and the cathode contacts 42 of the modules 10 are connected to the socket strip 82 in the second end rail 72. The side rails 70 are connected to the end rails 71, 72 with the four corner brackets 74. The grooves 80 are filled with the potting material 110 (FIG. 5) to encase the socket strip 82. The material 110 is then hardened. The reflective surface 14 is fixed to the back of the framed 12. The output terminals 16, 17 can then be connected to an electrical device to output electricity to the device when the modules 10 are exposed to light. In an alternative method, the socket strips 82 are connected to the modules 10 before being mounted in the grooves 80, so that the socket strips 82 are more easily manipulated when connecting to the modules 10.

In the figures cited below, parts labeled with primed and multiply-primed reference numerals correspond to parts labeled with equivalent unprimed numerals.

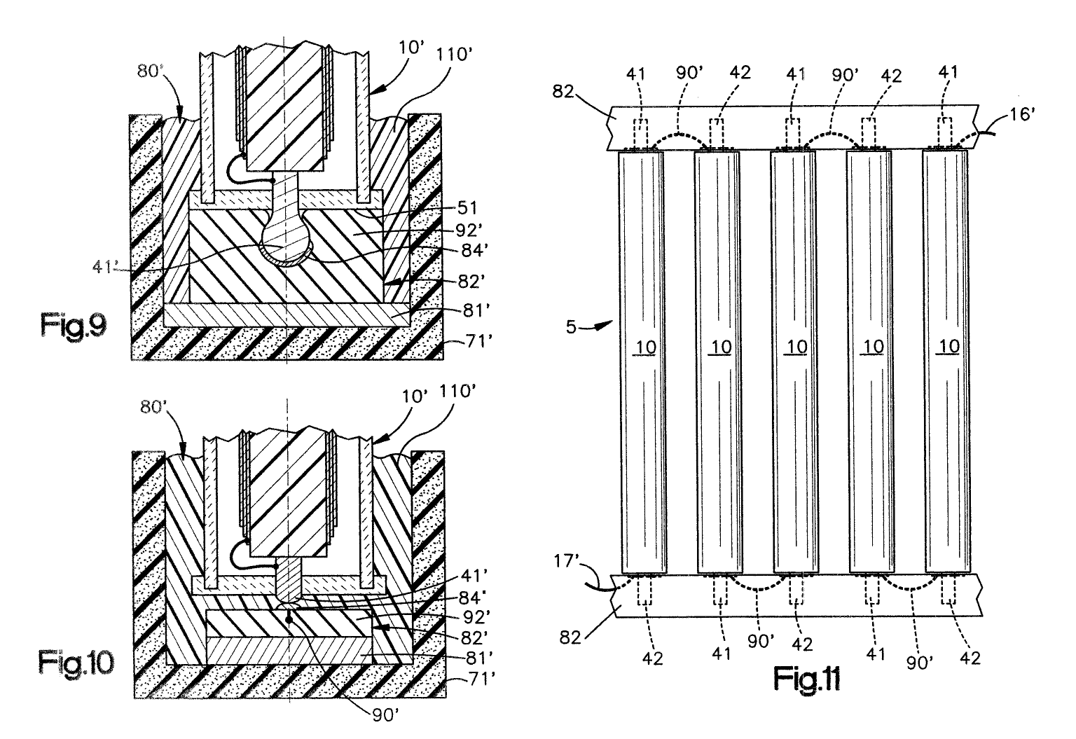

In the first embodiment, as shown in FIG. 5, the module contact 41 is portrayed as cylindrical and grasped by the socket contact 84. Alternatively, module contacts can have another shape and need not be grasped by the socket contact 84. For example, FIG. 9 shows a spherical module contact 41′ and an alternative socket strip 82′ in which the sheath 92′, instead of the socket 84, grasps the module contact 41′. The material surrounding the hole in the sheath 92′, instead of the contact 84′, is thus the socket in this embodiment securing the module 10 to the rail 71′. Additionally, in contrast to FIG. 5, the stiffening member 81′ in FIG. 9 is as wide as the groove 80′ to provide a snug fit, and the socket strip 84′ is narrower than the groove 80′. This enables the potting material 110′ to engage the stiffening module 81′ and both sides of the socket strip 82′.

FIG. 10 shows another alternative socket strip 82′. In contrast to the configurations shown in FIGS. 5 and 9, the strip 82′ of FIG. 10 neither receives nor secures the module contact 41′, and the contacts 41′, 84′ of both the module 10′ and the strip 82′ are button contacts and are both outside the sheath 92′. This enables the strip 82′ of FIG. 10 to be thinner than in the previous embodiments, and thus more flexible and more suitable for storing in rolls.

In the first embodiment, as shown in FIG. 6, the modules 10 are electrically connected in parallel. In another embodiment shown in FIG. 11, the modules 10 are connected in series. This can be achieved by flipping the axial orientation of every other module 10 in the array 5, so that the anode contact 41 of each module 22 is adjacent to a cathode contact 42 of an adjacent module 22. Each anode contact 41 can then be electrically connected by an electrical line 90′ to an adjacent cathode cell 22.

Although the photovoltaic surface 54 is preferably cylindrical as shown above, other shapes are possible as mentioned above. For example, FIG. 12 shows a module 10′ that has a tubular photocell 22′ having conductive inner and outer layers 31′ and 33′ and a photovoltaic middle layer 32′. The middle layer 32′ is tubular with a rectangular cross-section. It thus provides four contiguous orthogonal flat photovoltaic surface portions 55′ that face away from the axis A in different directions and together extend fully about the axis A. Like the cylindrical photocell configuration described above, this rectangular configuration can photovoltaically generate electricity from light rays directed toward the module 10′ from any radially-inward direction, even though not all such light rays could strike the respective surface portion 55′ perpendicularly. Similar choices of shape exist when defining any outer protective sleeve that fits over the cell(s) 22.

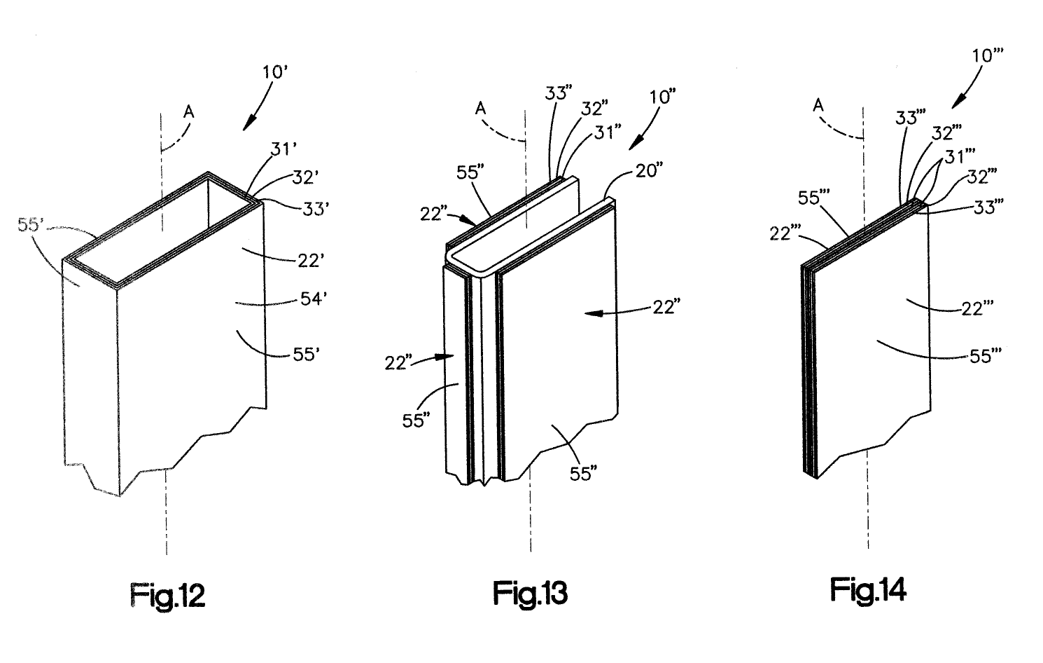

Each module 10 in the above example includes a single photovoltaic cell 22. Alternatively, each module 10 can have multiple cells. For example, FIG. 13 shows a module 10″ having three separate cells 22″ that together provide three separate orthogonal photovoltaic surface portions 55″ that face away from the axis A in three different directions. FIG. 14 shows a module 10′″ made of two photocells 22′″ glued back-to-back to provide two separate flat photovoltaic surfaces 55′″ facing away from each other and the axis A.

The module 10 can have one contiguous photovoltaic cell. Or, it can have several photovoltaic cells, connected in serial or in parallel. These cells can be made as a monolithic structure that has the plurality of cells scribed into the photovoltaic material during the semiconductor manufacturing stage. Examples of such monolithically integrated cells are disclosed in, for example, in U.S. Pat. No. 7,235,736, which is hereby incorporated by reference herein. Further, as noted above, the cross-sectional geometry of such an elongated module need not be limited to the cylindrical embodiment described above. Indeed, the cross-sectional geometry can be polygonal, e.g., an n-sided polygon where n is any positive integer greater than two. For example, the cross-sectional geometry can be square planar (n=4), a pentagon (n=5) and so forth. Moreover, the cross-sectional geometry can be any regular (e.g. square) or irregular closed form shape. In some embodiments, all or a portion of the elongated module can be characterized by a cross-section bounded by any one of a number of shapes. For instance, the bounding shape can be any one of circular, ovoid, or any shape characterized by one or more smooth curved surfaces, or any splice of smooth curved surfaces. The bounding shape can also be linear in nature, including triangular, rectangular, pentangular, hexagonal, or having any number of linear segmented surfaces. The bounding shape can be an n-gon, where n is 3, 5, or greater than 5. Or, the cross-section can be bounded by any combination of linear surfaces, arcuate surfaces, or curved surfaces. The bounding shape can be any shape that includes at least one arcuate edge.

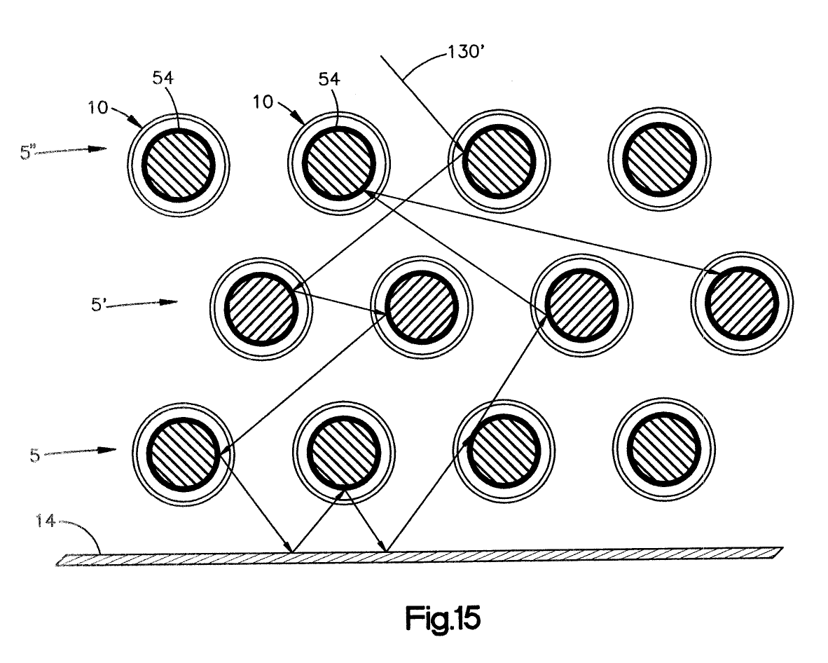

FIG. 15 shows a two-dimensional array formed from three one-dimensional arrays 5, 5′, and 5″ stacked one over the other. This can be achieved by stacking three panels like the panel 1 (FIG. 1) described above. The reflective surface 14 is mounted behind the bottom array 5. A light ray 130′ can be reflected any number of times from any number of photovoltaic surfaces 54 of the three arrays 5, 5′, and 5″ and from the reflective surface 14. The increased number of cell surfaces 54 being exposed to the light ray 130′ increases efficiency of converting that light ray 130′ to electricity.

The reflective surface 14 can be a self-cleaning surface such as, for example, any of the self-cleaning surfaces disclosed in U.S. patent application Ser. No. 11/315,523, filed Dec. 21, 2005 which is hereby incorporated by reference herein for the purpose of disclosing such surfaces.

In the exemplary embodiments, each photocell 22 is sealed in a transparent protective tube 24 (FIG. 3A). Alternatively, the tube 24 can be replaced with a protective coating or omitted entirely. The potting material 110 could then form a seal with the coating or with the photocell 22 itself. In some embodiments, as depicted in FIG. 16, photovoltaic modules 10 within the solar cell assembly apparatus 1, as disclosed in the present application, include flat solar cell panels 34. Referring to FIG. 16, multiple solar cell panels 34 are assembled together and placed within a frame 12. The frame 12 is assembled by side rails 72 and side rails 70. In some embodiments, the flat solar cell panels are bifacial. In some embodiments, the flat solar cell panels are monofacial. In some embodiments, the side rails 72 and side rails 70 are held together by corner support members 74, which provide further structure integrity to the frame 12. In some embodiments, the corner support members 74 are fixed on a stand 84. Still referring to FIG. 16, a stiffening member 81 and a socket strip 82 are bundled together and fixed within the grooves 80 of side rails 70 and end rail 72.

In some embodiments, the side rails 70 and end rails 72 are 20 centimeters or longer, 50 centimeters or longer, 1 meter or longer, 2 meters or longer, 5 meters or longer, 10 meters or longer, and 20 meters or longer. In some embodiments, the side rails 70 are 10 centimeters or longer, 20 centimeters or longer, 50 centimeters or longer, 1 meter or longer, 1.5 meters or longer, 2 meters or longer, or 5 meters or longer.

Structural Support by a Stiffening Member. The pultruded end rails 72 have high unidirectional strengths dependent upon the pulling direction of the reinforcement fibers 75. As discussed above, reinforcement fibers may take various forms (e.g., as threads, roving strands mats, or fabrics) and be implemented to provide structural integrity in various directions. Under most circumstances, the final pultruded products have high tensile strength along the pulling direction of the reinforcement fibers 75. Referring to FIG. 2C, which depicts a sectional view of end rail 72, end rail 72 has a concave groove 80. In some embodiments, the reinforcement fibers 75 are pulled such that they are aligned along direction l-l′. The resulting end rail 72 has great tensile strength and support along direction l-l′. End rail 72 as depicted in FIGS. 2C and 2D, however, may have less structural integrity along direction 2-2′. In some embodiments, as depicted in FIGS. 2E, 2F and 2G, reinforcement fibers 75 may be oriented differently from direction l-l′. The stiffening members 81 are added to the end rail 72 to further reinforce pultruded frames 12. In some embodiments, the stiffening member 81 occupies the full width of the concave groove 80, for example, as depicted in FIG. 9. In some embodiments, the stiffening member 81 does not fully occupy the full width of concave groove 80, as depicted in FIG. 10. For example, in some embodiments, the width of the stiffening member 81 (Wₛₘ) occupies about 20% or more, 40% or more, 50% or more, 60% or more, 80% or more, or 90% or more or 95% or more of the width of the concave groove 80 (W_{g}). In some embodiments, the groove 80 has a width of 1 centimeter or more, 2 centimeters or more, 3 centimeters or more, 5 centimeters or more, 8 centimeters or more, 10 centimeters or more, 15 centimeters or more, 20 centimeters or more, 25 centimeters or more, 35 centimeters or more, 50 centimeters or more, 75 centimeters or more, 100 centimeters or more, 150 centimeters or more, 200 centimeters or more, 250 centimeters or more, or 500 centimeters or more.

In some embodiments, as depicted in FIGS. 2A and 2B, the stiffening member 81 is a straight metal bar. In some embodiments not depicted, the stiffening member 81 is a roughly straight metal bar. In some embodiments, the stiffening member 81 is a flat metal tube.

In some embodiments, the stiffening member 81 is not a solid bar. For example, as depicted in FIGS. 2C to 2G, the stiffening member 81 may be made of repeating patterns of shapes such as circles, ellipses, polygons (e.g. squares), periodic or nonperiodic waveform shapes (e.g. cosine), or zig-zag patterns, or any mixture thereof. In some embodiments, for example, a wave-like or zig-zag patterned stiffening member 81 may be made of high strength thick metal wires.

In some embodiments, the stiffening member 81 is not attached to the bottom of the concave groove 80. Instead, the stiffening member 81 may be attached to either side 80-1 and 80-2 (FIG. 2C) of the concave groove 80. In some embodiments, the stiffening member 81 is attached to the outer surface of the end rail 72.

In some embodiments, the stiffening member 81 comprises metal elements such as aluminum, copper, iron, titanium, zinc, magnesium, steel, potassium, cobalt, nickel, copper, rare earth metals, gold, mercury, lead, bismuth, zirconium, or any combination thereof.

In some embodiments, the stiffening member 81 is made of one or more alloys of aluminum, iron, nickel, or copper. In some embodiments, the stiffening member 81 is embedded within the end rail 71 or 72 as an integrated part of the structure. For example, it is possible to embed a stiffening member 81 in the pulling stage of the pultrusion process such that the stiffening member 81 will be fused with the final pultruded products.

Pultrusion and Reinforcement Fibers. Pultrusion is a continuous process for manufacturing composites with a constant or near constant cross-sectional shape. The process consists of pulling a fiber reinforcing material through a resin impregnation bath and into a shaping die where the resin is subsequently cured. Heating to both gel and cure the resin is sometimes accomplished entirely within the die length, which can be, for example, on the order of 76 cm (30 inches) long. In other variations of the process, preheating of the resin-wet reinforcement is accomplished by dielectric energy prior to entry into the die, or heating may be continued in an oven after emergence from the die. The resin undergoes polymerization within the heated die. The final formed product is cut to suitable sizes by a cutting station. The pultrusion process yields continuous lengths of material with high unidirectional strengths. Details of a pultrusion process are disclosed, for example, in U.S. Pat. Nos. 3,960,629 to Goldsworthy et al., 4,032,383 to Goldsworthy et al., and 5,617,692 to Johnson et al., each of which is hereby incorporated by reference herein by its entirety.

In embodiments in accordance with the present application, reinforcement fibers 75 (e.g., natural or manufactured fibers) are embedded in end rails 71 and 72 during the pultrusion process of forming end rails 71 and 72. In some embodiments, the reinforcement fibers 75 are also embedded in side rails 70 during the pultrusion process of forming side rails 70. In preferred embodiments, the reinforcement fibers 75 are synthetic fibers, e.g., glass, organic or carbon fibers.

In some embodiments, the reinforcement fibers 75 are manufactured from natural cellulose, including rayon, modal, and the more recently developed Lyocell. Cellulose-based fibers are of two types, regenerated or pure cellulose such as from the cupro-ammonium process and modified or derivitized cellulose such as the cellulose acetates. In some embodiments, the reinforcement fibers 75 are manufactured from specific glass formulas and optical fiber, or made from purified natural quartz. In some embodiments, the reinforcement fibers 75 are metallic fibers that can be drawn from ductile metals such as copper, gold or silver and extruded or deposited from more brittle ones such as nickel, aluminum or iron. In some embodiments, the reinforcement fibers 75 are basalt fibers made from extremely fine fibers of basalt, which is composed of the minerals plagioclase, pyroxene, and olivine.

In some embodiments, the reinforcement fibers 75 are synthesized based on synthetic chemicals, for example, those from petrochemical sources rather than arising from natural materials by a purely physical process. For example, the reinforcement fibers 75 can be synthesized from polyamide nylon, PET or PBT polyester, phenol-formaldehyde (PF), polyvinyl alcohol fiber (PVOH), polyvinyl chloride fiber (PVC), polyolefins (PP and PE), or acrylic polymers, although pure polyacrylonitrile PAN fibers are used to make carbon fiber by roasting them in a low oxygen environment. In some embodiments, the reinforcement fibers 75 are made from traditional acrylic fibers. In some embodiments, the reinforcement fibers 75 are made from aromatic nylons such as Kevlar and Nomex that only thermally degrade at high temperatures and do not melt. In some embodiments, the reinforcement fibers 75 are made from fibers have strong bonding between polymer chains (e.g., aramids), or extremely long chains (e.g., Dyneema or Spectra). In some embodiments, the reinforcement fibers 75 are elastomers such as spandex and urethane fibers. In some embodiments, the reinforcement fibers 75 are Carbon fibers and PF fibers that are two resin-based fibers and are not thermoplastic. For example, in some embodiments, carbon fibers are made out of long, thin filaments of carbon sometimes transferred to graphite. A common method of making carbon fibers is the oxidation and thermal pyrolysis of polyacrylonitrile (PAN), a polymer used in the creation of many synthetic materials. In some embodiments, the reinforcement fibers 75 are glass fibers. Fiberglass or glass fiber is made from extremely fine fibers of glass. Glass fiber is formed when thin strands of silica-based or other formulation glass is extruded into many fibers with small diameters suitable for textile processing. Glass is unlike other polymers in that, even as a fiber, it has little crystalline structure as amorphous solid. The properties of the structure of glass in its softened stage are very much like its properties when spun into fiber. Glass fibers provide insulation, structural reinforcement, heat resistance, corrosion resistance, and high strength.

The reinforcement fibers 75 are implemented in the pultrusion process in various forms. In some embodiments, the reinforcement fibers 75 are continuous filaments in discrete elongated pieces, similar to lengths of thread. In some embodiments, the reinforcement fibers 75 can be spun into filaments, thread, string or rope. In some embodiments, the reinforcement fibers 75 can also be matted into thin stripes. Fibers are often used in the manufacture of other materials.

The aforementioned fiber materials are commercially available from sources that include, but are not limited to Fibre Glast Developments Corporation (Brookville, Ohio), Carbon Fiber Works, Inc (Starke, Fla.), Saint-Gobain Vetrotex America, Inc. (Valley Forge, Pa.), and Owens Corning Corporation (Toledo, Ohio).

Exemplary Potting and Encapsulation Material Encapsulants and potting compounds are resins or adhesives that are used to encapsulate circuit boards and semiconductors, fill containers of electronic components, and infiltrate electrical coils. They provide environmental protection, electrical insulation and other specialized characteristics. In most embodiments in accordance with the present application, encapsulants and potting materials are used as adhesive, insulation, bonding agents, encapsulating coating, sealant or gap filling agent to enhance the mechanical integrity of the final solar cell assembly. Encapsulants and potting compounds belong to a broader category of electrical resins and electronic compounds that includes adhesives, greases, gels, pads, stock shapes, gaskets, tapes, and thermal interface materials. Most potting compounds are based on polymeric resins or adhesives; however, materials based on ceramic or inorganic cements are often used in high temperature applications. Some encapsulants and potting compounds are designed to form a thermally conductive layer between components or within a finished product. For example, these thermally conductive products are used between a heat-generating electrical device and a heat sink to improve heat dissipation.

Specifications for encapsulants and potting compounds include electrical, thermal, mechanical, processing, and physical properties. Electrical properties include electrical resistivity, dielectric strength, and dielectric constant or relative permittivity. Thermal properties include service temperature, thermal conductivity, and coefficient of thermal expansion (CTE). Mechanical properties include flexural strength, tensile strength, and elongation. Processing and physical properties include viscosity, process or curing temperature, process or cure time, and pot life. Encapsulants and potting compounds vary in terms of features. Many products that are designed for electrical and electronics applications provide protection against electrostatic discharge (ESD), electromagnetic interference (EMI), and radio frequency interference (RFI). Materials that are electrically conductive, resistive, insulating, or suitable for high voltage applications are also available. Flame retardant products reduce the spread of flames or resist ignition when exposed to high temperatures. Thermal compounds and thermal interface materials that use a phase change are able to absorb more heat from electronic devices or electrical components. In some embodiments, it is necessary to select encapsulants and potting compounds for solar cell assembly based on the geographic location where the solar cell assembly is to be installed. In some embodiments, encapsulants and potting compounds are selected based on multiple factors such as temperature, rainfall level and snowfall level of the location where the frame will be installed.

In some embodiments, common potting compounds and casting resins are used to fill, for example, the grooves 80 of the end rails 71 and 72. Potting material is used to secure members of a given solar cell assembly, for example, to secure the stiffening bar 81 to the bottom or sides of the grooves 80, or to the inner or outer surface of the end rail 71 or 72. In some embodiments, encapsulants are used to seal or cover electrical connections. In typical embodiments, encapsulant layers are less than 10 millimeters thick. In some embodiments, gap filling or underfill compounds are used to fill in gaps or spaces between two surfaces to be bonded or sealed, for example, the stiffening bar 81 to the bottom or sides of the grooves 80, or to the inner or outer surface of the end rail 71 or 72. Encapsulants and potting compounds are based on a variety of chemical systems. Examples of potting and encapsulant materials include but are not limited to, for example, Acrylic/Polyacrylate (excellent environmental resistance and fast-setting times compared to other resin systems), Bitumen/Coal Tar (water resistance and low cost), Bismaleimide (BMI) (high temperature resistance), Cellulosic/Cellulose, Ceramic/Inorganic Cement, Epoxy (high strength and low shrinkage during curing, toughness and resistance to chemical and environmental damage), fluoropolymers (e.g., PTFE/PVDF for superior chemical resistance and low friction), isoprene/polyisoprene, Liquid Crystal Polymer (LCP, high strength and temperature resistance), phenolics/formaldehyde resins (e.g., Melamine, Furan, etc., thermosetting molding compounds and adhesives that offer strong bonds and good resistance to high temperatures and corrosion), polyamides (e.g., Nylon as one example of strong hot-melt adhesives), polyamide-imide (PAI), polybutadiene (e.g., for dielectric potting compounds and coatings), polycarbonate (PC) (amorphous with high impact strength, clarity, mechanical and optical properties), polyethylene (PE), PET/PBT (Thermoplastic Polyester), polyester/vinyl ester, polyolefin, polypropylene (PP), polypropylene (PP) (hot-melt adhesive systems), polysulphide, polyurethane (PU, PUR), silicone, styrene/polystyrene, and vinyl (e.g., PVC/PVA/PVDC).

In some embodiments, polymers or resins used as potting and encapsulant materials may be cured using various technologies that include thermoplastic/hot melt methods, thermosetting methods (e.g., cross-linking/vulcanizing), room temperature based methods (e.g., curing/vulcanizing), UV/radiation based methods, and reactive/moisture based methods. Polymers or resins used as potting and encapsulant materials may also be cured in a single component system, a two component system or even a multi-component system.

Companies specializing in polymers or resins used as potting and encapsulant materials and associated technologies include, but are not limited to, DYMAX Corporation (Torrington, Conn.), GC Electronics (Rockford, Ill.), Gelest, Inc. (Morrisville, Pa.), GS Polymers, Inc. (Brea, Calif.), Henkel Corporation-Electronics (Irvine, Calif.), Hernon Manufacturing, Inc. (Sanford, Fla.), ITW Polymer Technologies-Insulcast Division (Montgomery, Pa.), Master Bond, Inc. (Hackensack, N.J.), National Starch and Chemical Co. (Bridgewater, N.J.) and Sauereisen, Inc. (Pittsburgh, Pa.).

Summary. The present application discloses a solar assembly apparatus that comprises one or more photovoltaic modules, a first end rail to which the first ends of the one or more photovoltaic modules are fixed, and a first stiffening member to which the first end rail is attached.

In some embodiments, the photovoltaic modules in the solar cell assembly disclosed in the present application are a plurality of electrically-interconnected elongated photovoltaic modules forming an array. Each elongated photovoltaic module in the plurality of elongated photovoltaic modules is elongated along an axis and has a first end and a second end that are axially opposite each other. Furthermore, each elongated photovoltaic module in the plurality of elongated photovoltaic modules has photovoltaic surface portions facing away from the axis in different directions to receive light to generate electricity.

In some embodiments, the photovoltaic modules in the solar cell assembly are single bifacial flat panel solar cells.

In some embodiments, the first stiffening member is permanently attached to the first end rail by a potting or encapsulant material. In some embodiments, the first stiffening member is embedded within the first end rail. In some embodiments, the first stiffening member has a long axis that is approximately parallel to a long axis of the first end rail. In some embodiments, the first stiffening member is a bar. In some embodiments, the first stiffening member is a hollow flat tube. In some embodiments, the first stiffening member is made of metal. In some embodiments, the first stiffening member is a metal strip. In some embodiments, the first stiffening member comprises a circular pattern, an elliptical pattern, or a polygonal pattern, a zig-zag pattern, a periodic-like pattern, or a near periodic-like pattern.

In some embodiments, the first rail comprises an outer surface and an inner surface side and the first stiffening member is attached to the outer surface. In some embodiments, the first rail comprises an outer surface and an inner surface and wherein the first stiffening member is attached to the inner surface.

In some embodiments, the first rail comprises a groove with a first side, a second side and a bottom side. The first stiffening member is attached to the bottom side. In some embodiments, the bottom side of the groove has a width (W_{g}) and the first stiffening member has a width (Wₛₘ), wherein W_{g} [symbol] Wₛₘ. In some embodiments, Wₛₘ is equal or more than 50% of W_{g}, 80% of W_{g}, or 95% of W_{g}.

In some embodiments, the first rail comprises a groove which contains a first side, a second side and a bottom side; and the first stiffening member is attached to the bottom side, the first side or the second side, or a combination thereof. In some embodiments, the first rail comprises an outer surface and an inner surface; and the first stiffening member is attached to the inner surface or the outer surface.

In some embodiments, the first stiffening member comprises aluminum, copper, iron, titanium, zinc, an alloy thereof, or any combination thereof. In some embodiments, the first stiffening member is made of steel or wood.

In some embodiments, a solar cell assembly disclosed in the present application has a second end rail to which the second ends of the elongated photovoltaic modules are fixed and a second stiffening member to which the second end rails are attached. In some embodiments, the second stiffening member is the same as the first stiffening member. In some embodiments, the second stiffening member is different from the first stiffening member.

In some embodiments, a solar cell assembly disclosed in the present application has a first side rail and a second side rail. The first side rail and the second side rail are connected with the first end rail and the second end rail. In some embodiments, a third stiffening member is attached to the first side rail. In some embodiments, the first stiffening member as disclosed in the present application has a width of 1 centimeter or more, 10 centimeters or more, 50 centimeters or more.

### ADDITIONAL EMBODIMENTS

### Embodiment 1

A solar assembly apparatus comprising:

one or more photovoltaic modules, each respective photovoltaic module in the one or more photovoltaic modules having a first end and an opposing second end;

a first end rail to which the first end of each photovoltaic module in the one or more photovoltaic modules is fixed; and

a first stiffening member to which the first end rail is attached.

### Embodiment 2

The solar cell assembly of embodiment 1, wherein the one or more photovoltaic modules are a plurality of electrically-interconnected elongated photovoltaic modules forming an array; wherein

each respective elongated photovoltaic module in the plurality of elongated photovoltaic modules is elongated along an axis and has a first end and a second end that are axially opposite each other, and

each respective elongated photovoltaic module in the plurality of elongated photovoltaic modules is configured to receive light to generate electricity by photovoltaic surface portions of the respective elongated photovoltaic module that face away from the axis in different directions.

### Embodiment 3

The solar cell assembly of embodiment 1 or 2, wherein the one or more photovoltaic modules is a single bifacial flat panel solar cell.

### Embodiment 4

The solar cell apparatus of any one of embodiments 1-3, wherein the first stiffening member is permanently attached to the first end rail by a potting or encapsulant material.

### Embodiment 5

The solar cell apparatus of any one of embodiments 1-3, wherein the first stiffening member is embedded within the first end rail.

### Embodiment 6

The solar cell apparatus of any one of embodiments 1-5, wherein the first stiffening member has a long axis that is approximately parallel to a long axis of the first end rail.

### Embodiment 7

The solar cell apparatus of any one of embodiments 1-6, wherein the first stiffening member is a bar.

### Embodiment 8

The solar cell apparatus of any one of embodiments 1-6, wherein the first stiffening member is a hollow flat tube.

### Embodiment 9

The solar cell apparatus of any one of embodiments 1-8, wherein the first stiffening member is made of metal.

### Embodiment 10

The solar cell apparatus of any one of embodiments 1-9, wherein the first stiffening member is a metal strip.

### Embodiment 11

The solar cell apparatus of any one of embodiments 1-10, wherein the first stiffening member is characterized by a cross-section that is circular, elliptical, a polygon, or a shape that has at least one arcuate edge.

### Embodiment 12

The solar cell apparatus of any one of embodiments 1-11, wherein the first stiffening member has a zig-zag shape, a periodic-like shape, or a near periodic-like shape.

### Embodiment 13

The solar cell apparatus of any one of embodiments 1-12, wherein the first rail comprises an outer surface and an inner surface and wherein the first stiffening member is attached to the outer surface.

### Embodiment 14

The solar cell apparatus of any one of embodiments 1-12, wherein the first rail comprises an outer surface and an inner surface and wherein the first stiffening member is attached to the inner surface.

### Embodiment 15

The solar cell apparatus of any one of embodiments 1-14, wherein the first rail comprises a groove with a first side, a second side, and a bottom side and wherein the first stiffening member is attached to the bottom side.

### Embodiment 16

The solar cell apparatus of claim 15, wherein the bottom side of the groove has a width (W_{g}) and the first stiffening member has a width (W_{sf}), wherein W_{g}≧W_{sf}.

### Embodiment 17

The solar cell apparatus of claim 16, wherein (0.95*W_{g})≧W_{sf}.

### Embodiment 18

The solar cell apparatus of claim 16, wherein (0.80*W_{g})≧W_{sf}.

### Embodiment 19

The solar cell apparatus of claim 16, wherein (0.50*W_{g})≧W_{sf}.

### Embodiment 20

The solar cell apparatus of any one of embodiments 1-14, wherein the first rail comprises a groove with a first side, a second side and a bottom side and wherein the first stiffening member is attached to the first side.

### Embodiment 21

The solar cell apparatus of any one of embodiments 1-14, wherein the first rail comprises a groove with a first side, a second side and a bottom side and wherein the first stiffening member is attached to the second side.

### Embodiment 22

The solar cell apparatus of any one of embodiments 1-21, wherein the first rail comprises an outer surface and an inner surface and wherein the first stiffening member is attached to the inner surface.

### Embodiment 23

The solar cell apparatus of any one of embodiments 1-21, wherein the first rail comprises an outer surface and an inner surface and wherein the first stiffening member is attached to the outer surface.

### Embodiment 24

The solar cell apparatus of any one of embodiments 1-23, wherein the first stiffening member comprises aluminum, copper, iron, titanium, zinc, an alloy thereof, or any combination thereof.

### Embodiment 25

The solar cell apparatus of any one of embodiments 1-23, wherein the first stiffening member is made of steel or wood.

### Embodiment 26

The solar cell apparatus of embodiment 2, further comprising:

a second end rail to which the second end of each respective elongated photovoltaic module in the one or more elongated photovoltaic modules are fixed; and

a second stiffening member to which the second end rail is attached.

### Embodiment 27

The solar cell apparatus of embodiment 26, wherein the second stiffening member is the same as the first stiffening member.

### Embodiment 28

The solar cell apparatus of embodiment 26, wherein the second stiffening member is different than the first stiffening member.

### Embodiment 29

The solar cell apparatus of embodiment 26, further comprising:

a first side rail and a second side rail, wherein the first side rail and the second side rail are connected to the first end rail and the second end rail.

### Embodiment 30

The solar cell apparatus of embodiment 29, further comprising:

a third stiffening member to which the first side rail is attached.

### Embodiment 31

The solar cell apparatus of any one of embodiments 1-30, wherein the first stiffening member has a width of 1 centimeter or more.

### Embodiment 32

The solar cell apparatus of any one of embodiments 1-30, wherein the first stiffening member has a width of 10 centimeters or more.

### Embodiment 33

The solar cell apparatus of any one of embodiments 1-30, wherein the first stiffening member has a width of 50 centimeters or more.

### REFERENCES CITED AND ALTERNATIVE EMBODIMENTS

All references cited herein are incorporated herein by reference in their entirety and for all purposes to the same extent as if each individual publication or patent or patent application was specifically and individually indicated to be incorporated by reference in its entirety for all purposes.

Many modifications and variations of this application can be made without departing from its spirit and scope, as will be apparent to those skilled in the art. The specific embodiments described herein are offered by way of example only, and the application is to be limited only by the terms of the appended claims, along with the full scope of equivalents to which such claims are entitled.

What is claimed:

1. A solar assembly apparatus comprising:
one or more photovoltaic modules, each respective photovoltaic module in the one or more photovoltaic modules having a first end and an opposing second end;
a first end rail to which the first end of each photovoltaic module in the one or more photovoltaic modules is fixed; and
a first stiffening member to which the first end rail is attached.

2. The solar cell assembly of claim 1, wherein the one or more photovoltaic modules are a plurality of electrically-interconnected elongated photovoltaic modules forming an array; wherein
each respective elongated photovoltaic module in the plurality of elongated photovoltaic modules is elongated along an axis and has a first end and a second end that are axially opposite each other, and
each respective elongated photovoltaic module in the plurality of elongated photovoltaic modules is configured to receive light to generate electricity by photovoltaic surface portions of the respective elongated photovoltaic module that face away from the axis in different directions.

3. The solar cell assembly of claim 1, wherein the one or more photovoltaic modules is a single bifacial flat panel solar cell.

4. The solar cell apparatus of claim 1, wherein the first stiffening member is permanently attached to the first end rail by a potting or encapsulant material.

5. The solar cell apparatus of claim 1, wherein the first stiffening member is embedded within the first end rail.

6. The solar cell apparatus of claim 1, wherein the first stiffening member has a long axis that is approximately parallel to a long axis of the first end rail.

7. The solar cell apparatus of claim 1, wherein the first stiffening member is a bar or a hollow flat tube.

8. The solar cell apparatus of claim 1, wherein the first stiffening member is made of metal.

9. The solar cell apparatus of claim 1, wherein the first stiffening member is a metal strip.

10. The solar cell apparatus of claim 1, wherein the first stiffening member is characterized by a cross-section that is circular, elliptical, a polygon, or a shape that has at least one arcuate edge.

11. The solar cell apparatus of claim 1, wherein the first stiffening member has a zig-zag shape, a periodic-like shape, or a near periodic-like shape.

12. The solar cell apparatus of claim 1, wherein the first rail comprises an outer surface and an inner surface and wherein the first stiffening member is attached to the outer surface or the inner surface.

13. The solar cell apparatus of claim 1, wherein the first rail comprises a groove with a first side, a second side, and a bottom side and wherein the first stiffening member is attached to the bottom side.

14. The solar cell apparatus of claim 13, wherein the bottom side of the groove has a width (W_{g}) and the first stiffening member has a width (W_{sf}), wherein W_{g}≧W_{sf}.

15. The solar cell apparatus of claim 14, wherein (0.95*W_{g})≧W_{sf}.

16. The solar cell apparatus of claim 14, wherein (0.50*W_{g})≧W_{sf}.

17. The solar cell apparatus of claim 1, wherein the first rail comprises a groove with a first side, a second side and a bottom side and wherein the first stiffening member is attached to the first side or the second side.

18. The solar cell apparatus of claim 1, wherein the first stiffening member comprises aluminum, copper, iron, titanium, zinc, an alloy thereof, or any combination thereof.

19. The solar cell apparatus of claim 1, wherein the first stiffening member is made of steel or wood.

20. The solar cell apparatus of claim 2, further comprising:
a second end rail to which the second end of each respective elongated photovoltaic module in the one or more elongated photovoltaic modules are fixed; and
a second stiffening member to which the second end rail is attached.

21. The solar cell apparatus of claim 20, wherein the second stiffening member is the same as the first stiffening member.

22. The solar cell apparatus of claim 20, wherein the second stiffening member is different than the first stiffening member.

23. The solar cell apparatus of claim 20, further comprising:
a first side rail and a second side rail, wherein the first side rail and the second side rail are connected to the first end rail and the second end rail; and
a third stiffening member to which the first side rail is attached.

24. The solar cell apparatus of claim 1, wherein the first stiffening member has a width of 1 centimeter or more.

25. The solar cell apparatus of claim 1, wherein the first stiffening member has a width of 10 centimeters or more.
